(19) United States
(12) Patent Application Publication
(10) Pub. No.: US 2015/0219704 A1
(43) Pub. Date: Aug. 6, 2015

(54) Electromagnetic Wave Visualization Device

(71) Applicants: Aya Ohmae, Tokyo (JP); Satoshi Nakamura, Tokyo (JP); Hitoshi Yokota, Tokyo (JP); Takashi Suga, Tokyo (JP)

(72) Inventors: Aya Ohmae, Tokyo (JP); Satoshi Nakamura, Tokyo (JP); Hitoshi Yokota, Tokyo (JP); Takashi Suga, Tokyo (JP)

(73) Assignee: Hitachi, Ltd., Chiyoda-ku, Tokyo (JP)

(21) Appl. No.: 14/420,951

(22) PCT Filed: Aug. 31, 2012
(86) PCT No.: PCT/JP2012/072100

§ 371 Date: Feb. 11, 2015

(51) Int. Cl. G01R 29/08

(52) U.S. Cl. CPC G01R 29/0871

(57) ABSTRACT

Provided is an electromagnetic wave visualization device capable of visualizing multiple sources of electromagnetic noise in real time in a far field and a near field. The electromagnetic wave visualization device includes a sensor configured to detect an electromagnetic wave and output a detection signal of intensity depending on energy level of the detected electromagnetic wave, a variable resistance connected to the sensor, and a resistance adjustment unit configured to adjust a resistance value of the variable resistance connected to the sensor. The electromagnetic wave is visually measured by adjusting a resistance value of the variable resistance at the adjustment unit.

### TECHNICAL FIELD

The present invention relates to an electromagnetic wave visualization device.

### BACKGROUND ART

Various electronic devices supporting social infrastructure are speeding up as becoming highly functional, and the devices are required to be designed so that electromagnetic noise emitted from the devices does not cause electromagnetic interference on wireless communications devices, which will be further introduced. In the case where electromagnetic interference occurs, a rapid survey on site is required, and a device for visualizing a source of such electromagnetic noise in real time is required.

PTL 1 (JP 2011-53055 A) and PTL 2 (JP 2000-214198 A) disclose a technique for visualizing an electromagnetic wave. PTL 1 states that “two pairs of antennas, i.e. four antennas, disposed on an X axis and a Y axis which are orthogonal to each another, or three antennas sharing one antenna, an image camera for capturing scenery of a measurement target region, a detection unit for detecting an antenna signal, a signal processor/analysis unit, and a display unit are included. The signal processor/analysis unit measures time differences Δtx and Δty of electromagnetic waves arriving at the antenna pairs disposed on the X axis and the Y axis, and specifies a divided region obtained by dividing the measurement target region based on the values of Δtx and Δty. The display unit displays the specified divided region by superimposing the region on scenery captured by the image camera.”

Also, PTL 2 states that “a displacing unit 19 for displacing a magnetic field probe 4 in the vicinity of a target to be measured, a magnetic field detection unit 6, and a calibration unit for calibrating a direction of the magnetic field probe 4, in which its directivity is maximum, to a direction of a magnetic field to be detected are included. The calibration unit includes a probe deflector 27 for changing a direction of a magnetic field probe, a unit for generating a magnetic field for calibration 5, and a control unit 7 for controlling an operation of the probe deflector. The control unit 7 changes a direction of the magnetic field probe 4 in a magnetic field for calibration by operating the probe deflector 27, and detects a direction of directivity of the magnetic field probe 4 from output of the magnetic field detection unit 6 at the time”.

### CITATION LIST

### Patent Literature

PTL 1: JP 2011-53055 A

PTL 2: JP 2000-214198 A

### SUMMARY OF INVENTION

### Technical Problem

In the technique described in PTL 1, an arrival direction is calculated by using an arrival time difference of electromagnetic waves at an antenna pair. Therefore, in the case where there are multiple wave sources, an appropriate time difference may not be detected, and an arrival direction may not be specified. Also, in the technique described in PTL 2, a sensor scans a surface of a target to be measured. Therefore, a source of electromagnetic noise in a device is easily found. On the other hand, due to the scan, the electromagnetic noise is not found in real time. Therefore, there is a problem that electromagnetic noise emitted at a burst may not easily be found.

As described above, it is hard to visualize multiple sources of electromagnetic noise in real time by the techniques described in PTL 1 and PTL 2.

Also, in actual measurement of electromagnetic noise, after an object emitting noise is specified by a distant electromagnetic field measuring device, an electromagnetic field is often measured in detail by using a near electromagnetic field measuring device to specify which part of the object is a cause of electromagnetic radiation. However, especially a large scale device cannot be installed in the near electromagnetic field measuring device. Also, even if a part of the large scale device is taken out and analyzed by the near electromagnetic field measuring device, a noise source in an operating environment cannot be specified since an actual operating environment of the device is different.

Therefore, the present invention provides an electromagnetic wave visualization device in which multiple sources of electromagnetic noise can be visualized in real time under an operating environment of the device in a far field and a near field.

### Solution to Problem

A first representative configuration of the invention is as follows: An electromagnetic wave visualization device includes a sensor configured to detect an electromagnetic wave and output a detection signal of intensity depending on energy level of the detected electromagnetic wave, a variable resistance connected to the sensor, and a resistance adjustment unit configured to adjust a resistance value of the variable resistance connected to the sensor. An electromagnetic wave is visually measured by adjusting the resistance value of the variable resistance at the adjustment unit.

### Advantageous Effects of Invention

According to the present invention, a source of an electromagnetic wave in a far field and a near field can be visualized in real time.

### BRIEF DESCRIPTION OF DRAWINGS

FIG. 1 is a configuration diagram of an electromagnetic wave visualization device according to an embodiment of the present invention.

FIG. 2 is a view illustrating a measurement example in a far field by the electromagnetic wave visualization device according to the embodiment of the present invention.

FIG. 3 is a view illustrating a measurement example in a near field by the electromagnetic wave visualization device according to the embodiment of the present invention.

FIG. 4 is a diagram illustrating a wave impedance.

FIG. 5 is a plan view of a low-reflective electromagnetic field sheet, which is a sensor unit according to a first embodiment of the present invention.

FIG. 6 is a cross-sectional view of the low-reflective electromagnetic field sheet illustrated in FIG. 5.

FIG. 7 is a diagram illustrating a digital potentiometer according to the first embodiment of the present invention.

FIG. 8 is a configuration diagram of an electromagnetic wave visualization device according to a second embodiment of the present invention.

FIG. 9 is a plan view of a low-reflective electromagnetic field sheet, which is a sensor unit according to the second embodiment of the present invention.

### DESCRIPTION OF EMBODIMENTS

### First Embodiment

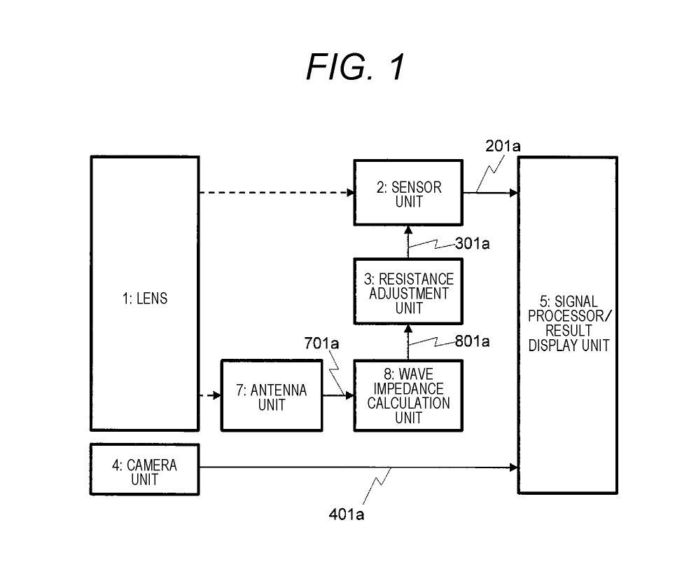

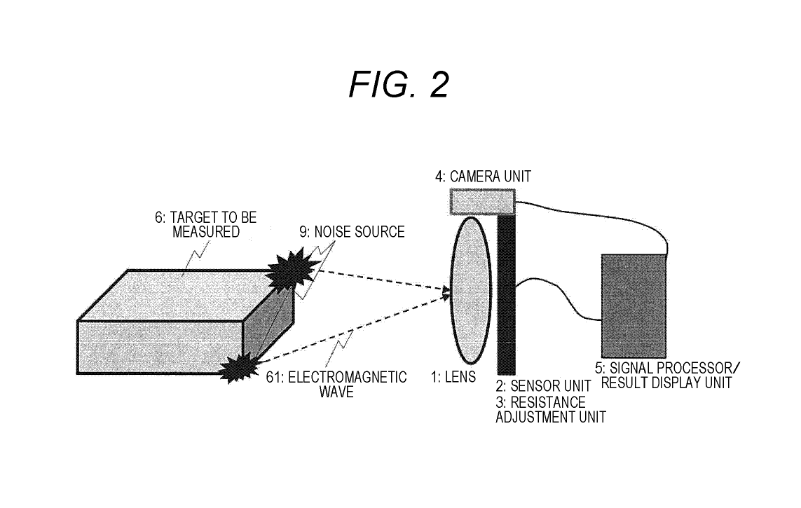

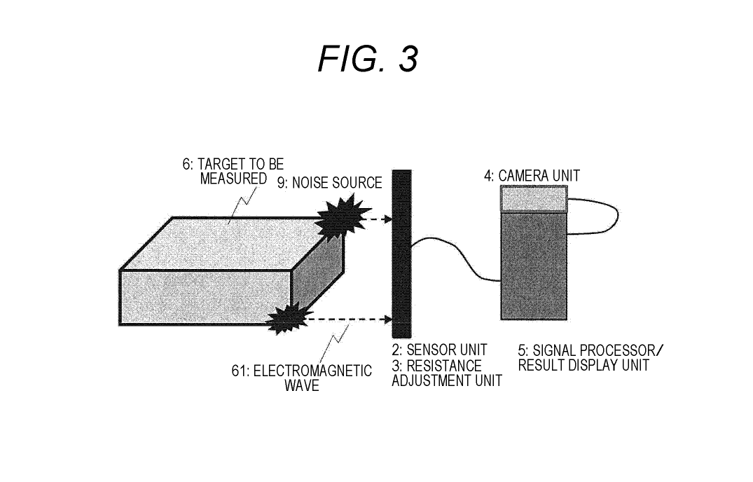

A configuration of an electromagnetic wave visualization device according to an embodiment of the present invention will be described with reference to FIGS. 1 to 6. FIG. 1 is a configuration diagram of the electromagnetic wave visualization device according to the embodiment. FIG. 2 is a view illustrating a measurement example in a far field by the electromagnetic wave visualization device according to the embodiment. FIG. 3 is a view illustrating a measurement example in a near field by the electromagnetic wave visualization device according to the embodiment.

As illustrated in FIG. 1, in the embodiment, the electromagnetic wave visualization device includes a lens 1, a sensor unit 2, a camera unit 4, a signal processor/result display unit 5, an antenna unit 7, a wave impedance calculation unit 8, and a resistance adjustment unit 3. The lens 1 has a separation function to separate an emission direction of an electromagnetic wave depending on an arrival direction (incident direction) of the electromagnetic wave. In the sensor unit 2, multiple sensors for inducing voltage by energy of an electromagnetic wave are disposed. The camera unit 4 is an imaging unit for capturing an image of a target to be measured and outputting an image signal of the captured image. The signal processor/result display unit 5 includes a signal processor for processing signals from the sensor unit 2 and the camera unit 4, and a display unit for displaying a result of the processing. The antenna unit 7 measures each of an electric field and a magnetic field in an electromagnetic field. The wave impedance calculation unit 8 calculates a wave impedance from values of the electric field and the magnetic field, which have been obtained by the antenna. The resistance adjustment unit 3 adjusts resistance values of the sensors based on the obtained wave impedance.

Each of the sensors in the sensor unit 2 is signal-connected to the signal processor/result display unit 5 via a transmission line 201a. The camera unit 4 is signal-connected to the signal processor/result display unit 5 via a transmission line 401a. The antenna unit 7 is signal-connected to the wave impedance calculation unit 8 via a transmission line 701a. The wave impedance calculation unit 8 is signal-connected to the resistance adjustment unit 3 via a transmission line 801a. The resistance adjustment unit 3 is signal-connected to the sensor unit 2 via a transmission line 301a.

The lens 1 converges an electromagnetic wave entering the lens, and changes an emission direction and an emission position of an electromagnetic wave emitted from the lens, depending on an arrival direction of the electromagnetic wave entering the lens. Electromagnetic waves of multiple arrival directions are converged at different positions so as to be focused. Multiple sensors are disposed in the sensor unit 2. The multiple sensors detect energy of electromagnetic waves emitted from the lens 1 and output detection signals of intensity depending on level of the detected energy. Therefore, a sensor at a position corresponding to a converging position (focus) of an electromagnetic wave entering the lens outputs a detection signal. More specifically, a sensor to output a detection signal differs depending on a converging position of an electromagnetic wave entering the lens.

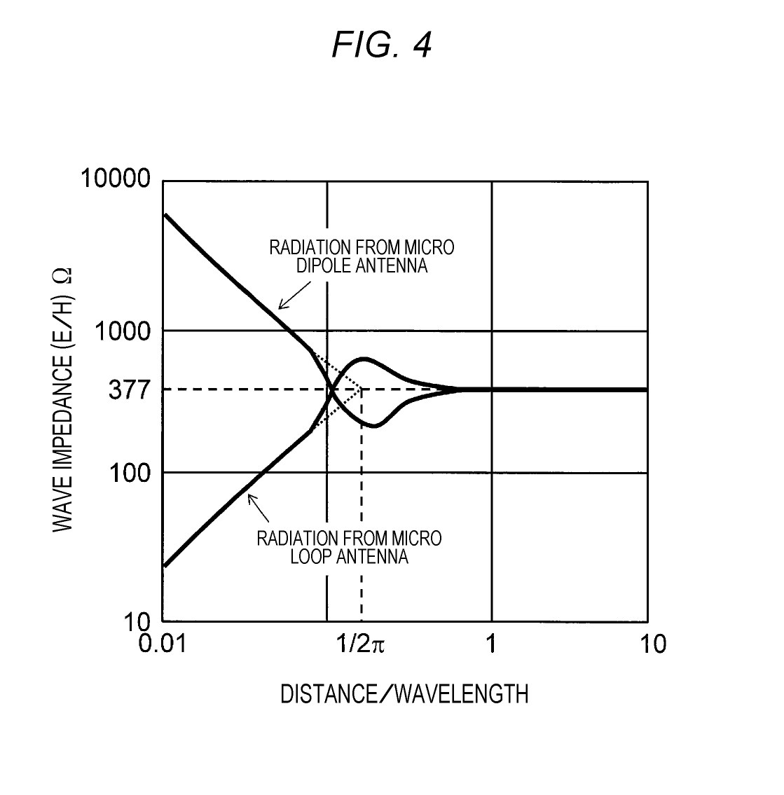

Herein, a principle of electromagnetic wave measurement by each of the sensors in the sensor unit 2 according to the present invention will be described. FIG. 4 is a diagram illustrating a wave impedance. A wave impedance is a ratio between an electric field E and a magnetic field H of an electromagnetic wave. A wave impedance becomes approximately 377Ω in any wave source if a ratio between a distance from a target to be measured 6 to the sensor unit 2 and the wavelength of an electromagnetic wave of the target to be measured 6 is equal to or greater than ½π.

If the distance between the target to be measured 6 and the sensor unit 2 is shorter than the above, a wave impedance differs depending on a form of a wave source of the target to be measured. If a resistance value of the sensor unit 2 and a wave impedance differ, reflection occurs on a sensor surface, and an electromagnetic wave is hard to measure. Therefore, a resistance value of the sensor unit 2 needs to be conformed to a wave impedance. If the resistance is equal to a wave impedance of an electromagnetic wave, the electromagnetic wave is absorbed at the sensor unit 2 without reflecting.

As a configuration for conforming the above resistance value to a wave impedance value, a variable resistance 31 is provided among the sensors in the present invention. A wave impedance is calculated from a value measured at the antenna unit 7, and the variable resistance 31 is adjusted so as to be equal to a wave impedance value obtained from a result of the calculation. As a result, reflection of an electromagnetic wave on a sensor surface caused by a difference between a resistance value of the sensor unit 2 and a wave impedance is suppressed, and highly accurate real-time measurement of an electromagnetic wave becomes possible.

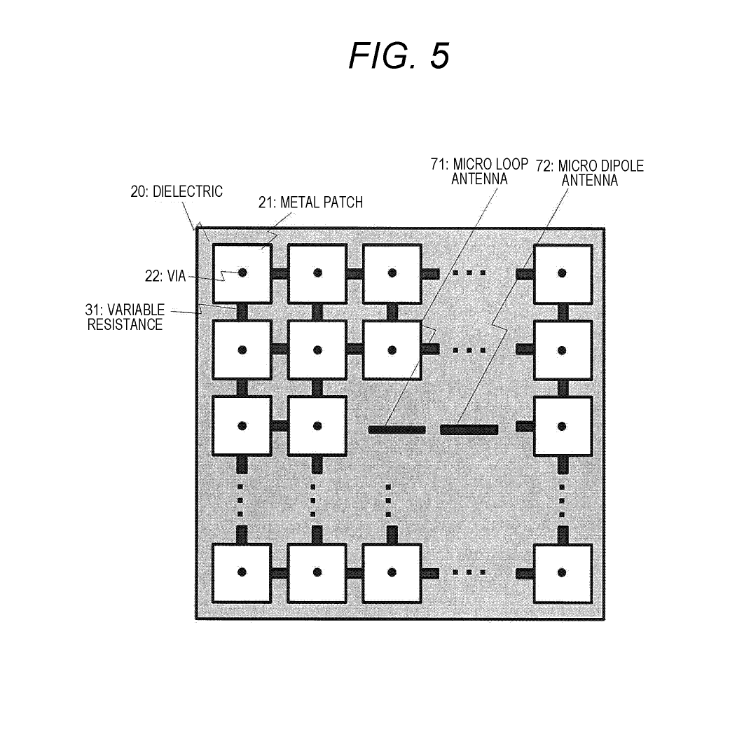

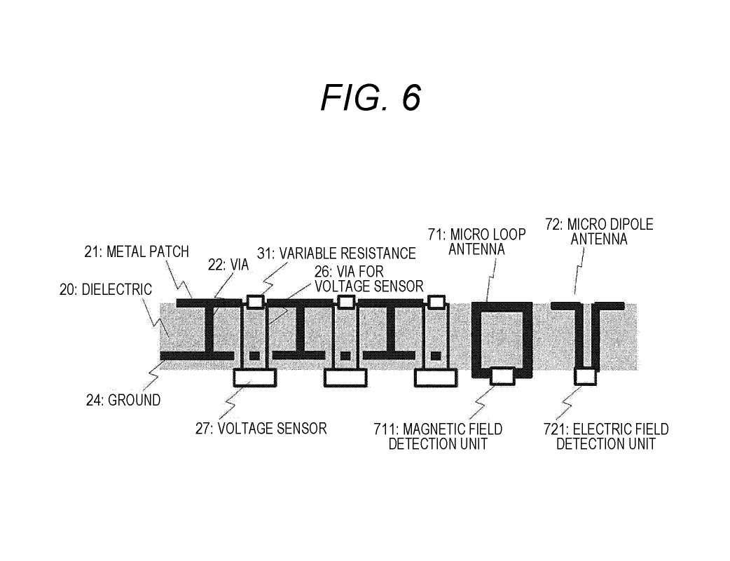

Next, configurations of the sensor unit 2 and the antenna unit 7 will be described in detail with reference to FIGS. 5 and 6. FIG. 5 is a plan view of a sheeted low-reflective electromagnetic field sensor including the sensor unit 2 and the antenna unit 7. FIG. 6 is a cross-sectional view of the low-reflective electromagnetic field sheet illustrated in FIG. 5.

The low-reflective electromagnetic field sensor according to the embodiment is, for example, realized by a periodic structure of mushroom-shaped metal. The periodic structure of mushroom-shaped metal is widely used because an electrical capacity and inductance for realizing low reflection can be controlled by a mushroom size.

As illustrated in FIG. 5, metal patches 21 are periodically disposed on a first layer which is a front surface of a plate-like dielectric 20. More specifically, the multiple metal patches 21 are disposed in rows (cross direction) and in columns (longitudinal direction) in a grid. The metal patches 21 are connected to one another via the variable resistances 31. A via 22, which will be described later, is provided at the center of each of the metal patches 21.

Each of the metal patches 21 is sufficiently small with respect to a wavelength λ of an electromagnetic wave to be measured, and the length of one side of the metal patch 21 is equal to or shorter than ( 1/10)λ. For example, in the case where a frequency of an electromagnetic wave to be measured is 2.4 GHz, one side of the metal patch 21 is assumed to be equal to or shorter than 12.5 mm. The metal patch 21 is not necessarily square although a square metal plate is used in the embodiment.

On the same surface as the metal patch 21, a micro loop antenna 71 and a micro dipole antenna 72 respectively measure a magnetic field and an electric field. A ratio between the magnetic field and the electric field is a wave impedance on a surface of the metal patch 21. Although the micro loop antenna 71 and the micro dipole antenna are arranged side by side in the embodiment, a distance between the antennas is preferably as small as possible and the antennas are preferably positioned so as not to interfere within a range of a variable resistance which changes depending on a required wave impedance. The antennas may be arranged anywhere as long as the above two conditions are satisfied.

Also, although two types of antennas, i.e., the micro loop antenna 71 and the micro dipole antenna 72 are used in the embodiment, the number of antennas is not limited to two. One antenna may be used as long as it can measure both of a magnetic field and an electric field.

As illustrated in FIG. 6, a ground 24, which is a conductor as a second layer opposing the first layer, is provided near a back surface of the dielectric 20. The ground 24 has a surface having an almost equal size to the dielectric 20. The ground 24 is connected to each of the metal patches 21 by the via 22 which is a conductor, with the dielectric 20 sandwiched therebetween. On the back surface of the dielectric 20, voltage sensors 27 are provided to correspond one-to-one with the variable resistances 31. Vias for a voltage sensor 26, which are conductors for connecting with the voltage sensor 27, are provided on both ends of the variable resistance 31. The via penetrates the dielectric 20 and the ground 24, and is connected to the voltage sensor 27. The ground 24 has a hole for passing the via for a voltage sensor 26, and the ground 24 and the via for a voltage sensor 26 are not electrically conducted.

The voltage sensor 27 detects a voltage induced at both ends of the variable resistance 31 through the via for a voltage sensor 26. The voltage sensor 27, for example, includes an amplifier, an AD converter, and a voltage measuring instrument. When any of the metal patches 21 included in the low-reflective electromagnetic field sheet is irradiated with an electromagnetic wave, a voltage is induced only to a resistance 25 connected to the metal patch 21 irradiated with the electromagnetic wave. Therefore, an arrival direction of the electromagnetic wave can be specified from a location of the voltage sensor 27 connected to the resistance 25.

At this point, if the resistance 25 is at 377Ω which is equal to a wave impedance, impedances of a space and the sensor unit 2 are matched, the electromagnetic wave does not reflect, and energy of the electromagnetic wave is absorbed by the sensor unit 2.

The dielectric 20 includes the micro loop antenna 71 and the micro dipole antenna 71 in addition to the sensor unit 2. If an area of the micro loop antenna is denoted by s, a magnetic field H is calculated by [Formula 1] from a voltage v induced at the loop antenna.

$$H = \frac{v}{ω {μ}_{0} S} \qquad [ Formula 1 ]$$

Herein, μ₀ denotes a dielectric constant in vacuum, ω denotes an angular frequency of a target to be measured. Also, an electric field E is calculated by [Formula 2] from a voltage v induced at a micro dipole antenna of effective length l.

$$E = \frac{v}{l} \qquad [ Formula 2 ]$$

A wave impedance Z₀ is calculated by [Formula 3] from the obtained magnetic field H and electric field E, and the variable resistance 31 is adjusted at the resistance adjustment unit 3 so that the wave impedance Z₀ and the variable resistance 31 become equal.

$${Z}_{0} = \frac{E}{H} \qquad [ Formula 3 ]$$

A magnetic field detection unit 711 of a micro loop antenna and an electric field detection unit 721 of a micro dipole antenna detect a voltage induced at each of the antennas, and a wave impedance is calculated at the wave impedance calculation unit 8 based on the voltage value.

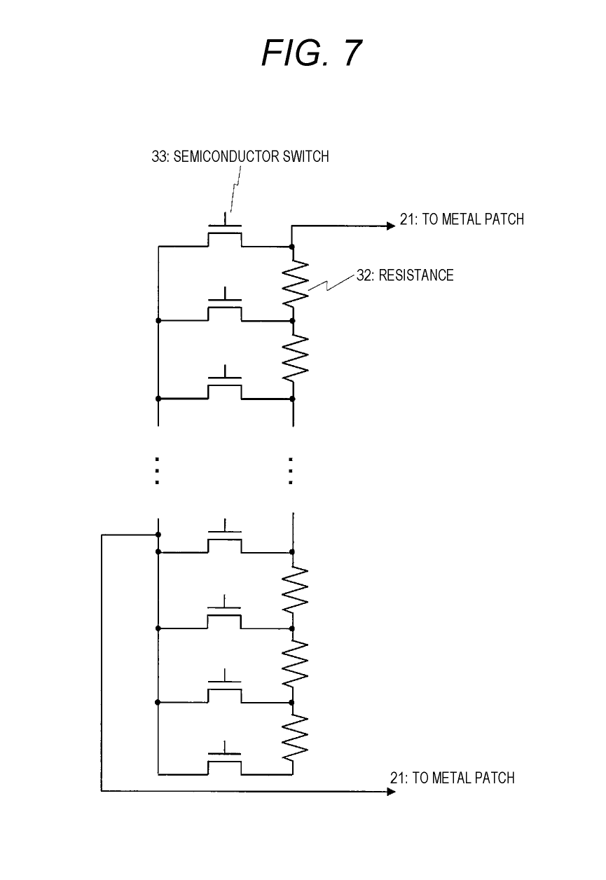

For example, a digital potentiometer as illustrated in FIG. 7 is used in the variable resistance 31. The digital potentiometer can change a resistance value by switching a semiconductor switch 33 by a signal from the resistance adjustment unit 3 described in FIG. 1. Therefore, by conforming the variable resistance 31 to a wave impedance value, impedances of the space and the sensor unit 2 are matched, an electromagnetic wave does not reflect even in the vicinity of a target to be measured, and energy of the electromagnetic wave is absorbed by the sensor unit 2.

The signal processor/result display unit 5 can receive a detection signal from each of multiple sensors of the sensor unit 2. When receiving the detection signal from any of the sensors of the sensor unit 2, the signal processor/result display unit 5 outputs a display signal including location information of the sensor, which has sent the detection signal, and intensity information of the received detection signal. Also, the signal processor/result display unit 5 has received an image signal of an image captured by the camera unit 4, and prepares and outputs a display signal in which a signal including sensor location information and information on intensity of the detection signal is superimposed on the image signal.

The signal processor/result display unit 5 can display a location of each of the multiple sensors of the sensor unit 2. When receiving a display signal, the signal processor/result display unit 5 displays, for example, on a liquid crystal display (LCD), locations of the sensors and intensity of a detection signal based on sensor location information and information on intensity of the detection signal, which are included in the display signal. Also, an image captured by the camera unit 4 is displayed at the same time.

In this manner, in the signal processor/result display unit 5, information including location information on a sensor, which has output a detection signal, and information on intensity of the detection signal is displayed by being superimposed on a measurement target image captured by the camera unit 4. For example, an electromagnetic field map in which a color display is changed depending on intensity of a detection signal may be displayed on a camera image. Also, in the case where the intensity of a detection signal is equal to or greater than a predetermined value, location information corresponding to a sensor with a predetermined value or more may be displayed by being superimposed on a measurement target image captured by the camera unit 4.

Cases of measuring a far field and a near field of an electromagnetic wave in the present invention will be described next.

First, the case of measuring a far field of an electromagnetic wave will be described. A far field of an electromagnetic wave is measured by the configuration illustrated in FIG. 2. For example, an electromagnetic wave 61 generated from a noise source 7 of the target to be measured 6 is separated at an electromagnetic wave lens 1, which is an emission direction separation unit. More specifically, depending on an arrival direction of an electromagnetic wave, an emission direction of an electromagnetic wave emitted from the electromagnetic wave lens 1 is changed, and the electromagnetic wave enters the sensor unit 2. The sensor unit 2 sets a variable resistance to 377Ω, and the sensor, in which energy is induced by incidence of an electromagnetic wave having passed through the electromagnetic wave lens 1, outputs a detection signal of intensity depending on level of the induced energy.

The signal processor/result display unit 5 recognizes a location (number) of a sensor, which has output the detection signal, and intensity of the detection signal. The signal processor/result display unit 5 internally includes a table associating the sensor location (number) with an arrival angle of an electromagnetic wave, and obtains the arrival angle of an electromagnetic wave with reference to the table based on the location information of the sensor which has output the detection signal. Also, the signal processor/result display unit 5 has received an image signal of an image captured by the camera unit 4. The signal processor/result display unit 5 realizes visualization of an electromagnetic wave by preparing a display signal in which a signal including sensor location information and information on intensity of the detection signal is superimposed on the image signal, and displaying a location of the noise source 7 of the target to be measured 6 and noise level on the image captured by the camera unit 4.

Next, the case of measuring a near field of an electromagnetic wave will be described. A near field is measured by the configuration in which the lens 1 is removed as illustrated in FIG. 3. For example, the electromagnetic wave 61 generated from the noise source 7 of the target to be measured 6 is detected by the micro loop antenna 71 and the micro dipole antenna 72, and a wave impedance value is calculated by the wave impedance calculation unit 8. A resistance value is determined from the obtained wave impedance value at the resistance adjustment unit 3, and a value of the variable resistance 31 arranged in the sensor unit 2 is changed.

In the sensor unit 2, a sensor, in which incident energy is induced, outputs a detection signal of intensity depending on level of the induced energy. The signal processor/result display unit 5 recognizes a location (number) of a sensor, which has output the detection signal, and intensity of the detection signal. The signal processor/result display unit 5 internally includes a table associating the sensor location (number) with an arrival angle of an electromagnetic wave, and obtains the arrival angle of an electromagnetic wave with reference to the table based on the location information of the sensor which has output the detection signal.

Also, the signal processor/result display unit 5 has received an image signal of an image captured by the camera unit 4. The signal processor/result display unit 5 realizes visualization of an electromagnetic wave by preparing a display signal in which a signal including sensor location information and information on intensity of the detection signal is superimposed on the image signal, and displaying a location of the noise source 7 of the target to be measured 6 and noise level on the image captured by the camera unit 4. A near field may be measured first by removing the sensor unit 2 and capturing a target to be measured by the camera unit 4, and then detecting an electromagnetic field after the sensor unit 2 is assembled, and displaying the electromagnetic field on an image in the signal processor/image display unit 5. Also, although the antenna unit 7 and the sensor unit 2 are provided on the same substrate in the embodiment, they may be provided separately. For example, an electromagnetic field map in which a color display is changed depending on intensity of a detection signal may be displayed on a camera image. Also, in the case where the intensity of a detection signal is equal to or greater than a predetermined value, location information corresponding to a sensor with a predetermined value or more may be displayed by being superimposed on a measurement target image captured by the camera unit 4.

As described above, according to the present invention, a sensor for detecting an electromagnetic field highly accurately detects and visualizes arrival and intensity of an electromagnetic wave depending on an arrival direction of the electromagnetic wave. Accordingly, an electromagnetic wave measurement with improved real-time performance becomes possible. Also, a wave impedance is obtained by a micro dipole antenna and a micro loop antenna, and an electromagnetic wave can be measured in real time by conforming a variable resistance of the sensor to the wave impedance.

### Second Embodiment

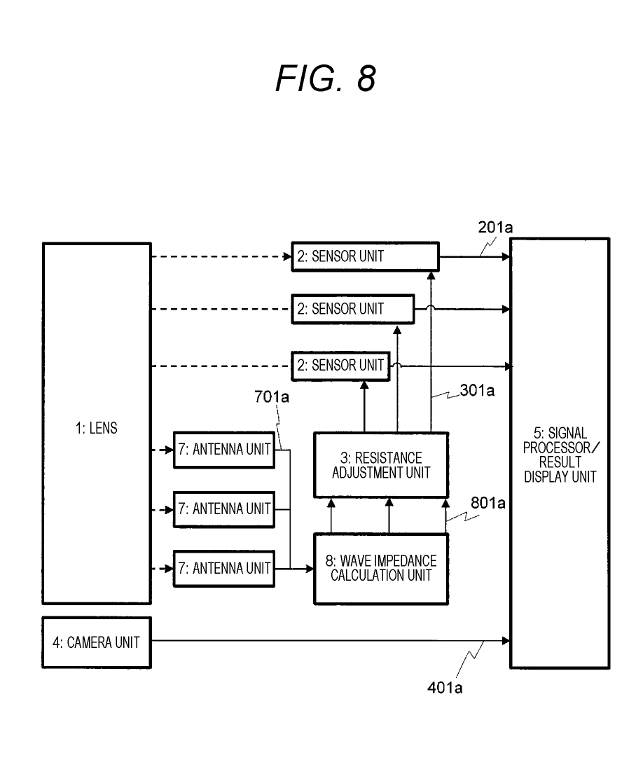

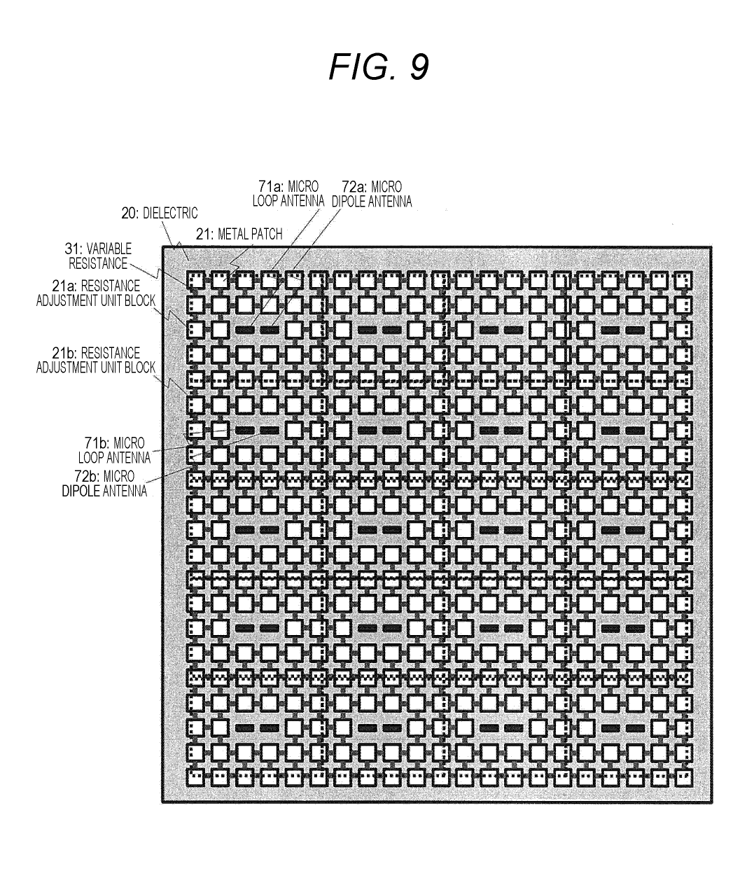

A second embodiment of the present invention will be described with reference to FIGS. 8 and 9. When a near field is measured, multiple antenna units 7 for calculating wave impedances may be disposed on a low-reflective electric field sheet as illustrated in FIG. 8. According to values obtained in the antenna units 7, a wave impedance of each of the antenna units 7 is calculated, and resistances of the sensor units 2 near the antenna units 7 are adjusted.

For example, as illustrated in FIG. 9, a wave impedance calculated from values of an electric field and a magnetic field, which have been obtained by a micro loop antenna 71(a) and a micro dipole antenna 72 (a) and a value of a variable resistance 31 in a resistance adjustment unit block 21 (a) are made equal, and a wave impedance calculated from values of an electric field and a magnetic field, which have been obtained by a micro loop antenna 71 (b) and a micro dipole antenna 72 (b) and a value of the variable resistance 31 in a resistance adjustment unit block 21(b) are made equal. In the measurement of a near field, an obtained value of an electromagnetic field significantly differs depending on a difference in a distance between a noise source of a target to be measured and each metal patch 21. Accordingly, a wave impedance may differ on a low-reflective electric field sheet. Therefore, the low-reflective electric field sheet is divided into blocks, a wave impedance is calculated for each block, and the variable resistance 31 is adjusted.

As a result, the variable resistance 31 can be adjusted corresponding to change in a wave impedance on the low-reflective electric field sheet, and a non-reflecting state of an electromagnetic wave on the low-reflective electric field sheet can be maintained. In the embodiment, although the antenna unit 7 is disposed on a low-reflective electric field sheet, the antenna unit 7 may be disposed separately from the low-reflective electric field sheet.

As described above, according to the present invention, a sensor for detecting an electromagnetic field highly accurately detects and visualizes arrival and intensity of an electromagnetic wave depending on an arrival direction of the electromagnetic wave. Accordingly, an electromagnetic wave measurement with improved real-time performance becomes possible. Also, a wave impedance of each block is obtained from a micro dipole antenna and a micro loop antenna, and an electromagnetic wave can be measured in real time by conforming a surrounding variable resistance to the wave impedance.

### REFERENCE SIGNS LIST

1 Emission direction separation unit
2 Sensor unit
11 Lens
3 Resistance adjustment unit
4 Camera unit
5 Signal processor/result display unit
6 Target to be measured
7 Antenna
8 Wave impedance calculation unit
9 Noise source
201a Transmission line
301a Transmission line
401a Transmission line
701a Transmission line
801a Transmission line
20 Dielectric
21 Metal patch
22 Via
24 Ground
26 Via for voltage sensor
31 Variable resistance
32 Resistance
33 Semiconductor switch
61 Electromagnetic wave
71 Micro loop antenna
711 Magnetic field detection unit
72 Micro dipole antenna
721 Electric field detection unit
21a, 21b Resistance adjustment unit block
71a, 71b Micro loop antenna
72a, 72b Micro dipole antenna

1. An electromagnetic wave visualization device comprising:
a sensor configured to detect an electromagnetic wave and output a detection signal of intensity depending on energy level of the detected electromagnetic wave;
a variable resistance connected to the sensor; and
a resistance adjustment unit configured to adjust a resistance value of the variable resistance connected to the sensor,
wherein the electromagnetic wave is visually measured by adjusting the resistance value of the variable resistance at the adjustment unit.

2. The electromagnetic wave visualization device according to claim 1, wherein the resistance value of the variable resistance is adjusted to a wave impedance value of the electromagnetic wave at the adjustment unit.

3. The electromagnetic wave visualization device according to claim 2, comprising:
an electric field measuring antenna configured to measure an electric field;
a magnetic field measuring antenna configured to measure a magnetic field; and
a wave impedance calculation unit configured to calculate a wave impedance from values of an electric field and a magnetic field obtained by the electric field measuring antenna and the magnetic field measuring antenna,
wherein the resistance adjustment unit adjusts a value of the variable resistance to be equal to a wave impedance value obtained at the impedance calculation unit.

4. The electromagnetic wave visualization device according to claim 3, wherein the electric field measuring antenna and the magnetic field measuring antenna are disposed adjacently.

5. The electromagnetic wave visualization device according to claim 2, comprising:
an electromagnetic field measuring antenna capable of measuring an electric field and a magnetic field;
a wave impedance calculation unit configured to calculate a wave impedance from values of an electric field and a magnetic field obtained by the electromagnetic field measuring antenna,
wherein the resistance adjustment unit adjusts a value of the variable resistance to be equal to a wave impedance value obtained at the impedance calculation unit.

6. The electromagnetic wave visualization device according to claim 1, comprising:
a voltage sensor connected to the variable resistance,
wherein the electromagnetic wave is detected by a voltage induced by the voltage sensor.

7. The electromagnetic wave visualization device according to claim 1, wherein the variable resistance is a digital potentiometer.

8. An electromagnetic wave visualization device comprising:
multiple sensors configured to detect electromagnetic waves and output detection signals of intensity depending on energy level of the detected electromagnetic waves;
a variable resistance connected to each of the multiple sensors;
a resistance adjustment unit configured to adjust a resistance value of the variable resistance connected to each of the multiple sensors;
a processor capable of receiving the detection signals from the multiple sensors, the processor being configured to output display signals including information on arrival directions of the electromagnetic waves based on location information on the sensors which have sent the detection signals, when receiving the detection signals from the sensors; and
a display unit capable of displaying each of the arrival directions of the multiple electromagnetic waves, the display unit being configured to, when receiving the display signals, display arrival directions of the electromagnetic waves based on locations of the sensors, based on location information of the sensors which is included in the display signals.

9. The electromagnetic wave visualization device according to claim 8, wherein the processor outputs display signals including intensity information on the detection signals together with location information on the sensors which have sent the detection signals, and
the display unit displays depending on intensity of the detection signals when displaying arrival directions of the electromagnetic waves based on locations of the sensors.

10. The electromagnetic wave visualization device according to claim 9, wherein the processor displays in a predetermined manner in the case where intensity of the detection signals received from the sensors is equal to or greater than a predetermined value, and
the display unit displays in a predetermined manner regardless of the intensity of the detection signals when displaying the arrival directions of the electromagnetic waves.

11. The electromagnetic wave visualization device according to claim 8, comprising a camera unit configured to capture an image of a target to be measured and output an image signal of the captured image,
wherein the processor outputs a display signal including the image signal and an arrival direction of an electromagnetic wave obtained from location information on the sensor, which has sent the detection signal, with reference to a table when receiving the image signal from the camera unit and the detection signal from the sensor, and
when receiving the display signal, the display unit displays the arrival direction of the electromagnetic wave by superimposing the arrival direction on an image of the image signal based on the image signal and information on the arrival direction of the electromagnetic wave obtained based on the location information on the sensor, the image signal and the information on the arrival direction being included in the display signal.

12. The electromagnetic wave visualization device according to claim 1, comprising an emission direction separation unit configured to change an emission direction of an electromagnetic wave depending on an incident direction of the electromagnetic wave,
wherein the sensor detects an electromagnetic wave emitted from the emission direction separation unit.

13. The electromagnetic wave visualization device according to claim 12, wherein the emission direction separation unit includes a magnetic wave lens.
